(19) United States
(12) Patent Application Publication
(10) Pub. No.: US 2026/0036915 A1
(43) Pub. Date: Feb. 5, 2026

(54) METHOD FOR OPERATING A MASK INSPECTION DEVICE, CONTROL SYSTEM FOR A MASK INSPECTION DEVICE, MASK INSPECTION DEVICE, COMPUTER PROGRAM PRODUCT

(71) Applicant: Carl Zeiss SMT GmbH, Oberkochen (DE)

(72) Inventor: Maximilian Henning, Huettlingen (DE)

(21) Appl. No.: 19/267,811

(22) Filed: Jul. 14, 2025

(30) Foreign Application Priority Data
Aug. 1, 2024 (DE) 102024121957.2

(51) Int. Cl. G03F 7/00; G06T 7/246; G06T 7/73

(52) U.S. Cl. CPC G03F 7/70516; G03F 7/70033; G03F 7/7085; G06T 7/248; G06T 7/74; G06T 2207/30148

(57) ABSTRACT

A method for operating a mask inspection device, in which a photomask illuminated with EUV radiation is imaged onto an image sensor of an EUV camera by a projection lens. The photomask is borne by a positioning system, the positioning system being designed to change the position of the photomask relative to the projection lens. The photomask is moved relative to the projection lens during an exposure process of the EUV camera so that an image line is captured. An image structure included in the image line is compared with a reference structure and a variance between the image structure and the reference structure results in the positioning system being actuated in order to perform a corrective movement of the photomask. The invention also relates to a mask inspection device, a control system and a computer program product.

### CROSS-REFERENCE TO RELATED APPLICATION

The present application claims the priority of the German patent application DE 10 2024 121 957.2, filed on Aug. 1, 2024, the entire contents of which are incorporated herein by reference.

### TECHNICAL FIELD

The invention relates to a method for operating a mask inspection device, a control system for a mask inspection device, a mask inspection device and a computer program product.

### BACKGROUND

Photomasks are used in microlithographic projection exposure apparatuses, which are used to produce integrated circuits with particularly small structures. The photomask illuminated by very short-wave extreme ultraviolet radiation (EUV radiation) is imaged onto a lithography object in order to transfer the mask structure to the lithography object.

To ensure that the image produced on the lithography object is of high quality, it is necessary for the photomask to be true to size and not adversely affected by contamination. It is known practice to subject photomasks to an inspection, either prior to the operation in a microlithographic projection exposure apparatus or during an interruption of operation. For this purpose, a mask inspection device is used to generate a so-called aerial image of a portion of the photomask, in which the photomask is imaged onto an image sensor of an EUV camera rather than onto a lithography object. The imaging onto the image sensor can be taken as a basis for making an assessment as to whether the photomask is free of defects and contamination.

Heat is supplied to the projection lens of the mask inspection device during operation, which may be accompanied by thermal expansion of components of the projection lens. Thermal deformation can cause the image on the image sensor to drift. The drift can cause image lines to be shifted relative to one another, which can result in an image of the photomask composed of the image lines not having the optimum quality.

### SUMMARY

The invention is based on the aspect of presenting a method for operating a mask inspection device, a control system for a mask inspection device, a mask inspection device and a computer program product that reduce the aforementioned disadvantages. The aspect is achieved by the features of the independent claims. Advantageous embodiments are specified in the dependent claims.

A method according to the invention for operating a mask inspection device involves a photomask illuminated with EUV radiation being imaged onto an image sensor of an EUV camera by a projection lens. The photomask is borne by a positioning system, the positioning system being designed to change the position of the photomask relative to the projection lens. The photomask is moved relative to the projection lens during an exposure process of the EUV camera so that an image line is captured. A structure included in an image line is compared with a reference structure and a variance between the structure and the reference structure results in the positioning system being actuated in order to perform a corrective movement of the photomask.

In a mask inspection device, the field of view on the surface of the photomask corresponding to the area of the image sensor is small in relation to the area of the photomask. A scanning movement of the positioning system moves the photomask relative to the image sensor during an exposure process. This makes it possible to capture an image line extending over the length of the photomask in a continuous exposure process. Unlike in the case of an image line composed of single images, however, there is no way of deriving evidence of a drift in the projection lens from variances between adjacent single images in a continuously exposed image line such as this. While a drift for a plurality of single images has the effect that the single images do not match at the edges, in the case of a continuously captured image line it is not possible to distinguish whether an oblique structure in the image line is actually oblique or whether a structure that is actually straight on the photomask only appears oblique due to a drift in the image line. Conventional methods for image correction therefore cannot be used in connection with a mask inspection device according to the invention.

The invention proposes performing a comparison between an image structure included in an image line and a reference structure and taking the degree of variance as a basis for actuating the positioning system so that the positioning system performs a corrective movement that counteracts the variance. An image structure is information included in the image data about a structure of the photomask. The corrective movement can be performed in particular for the purpose of correcting a drift that results from a thermal deformation of the projection lens. The drift can be determined by means of comparison with the reference structure. Alternatively or additionally, the drift can be determined from a stitching method. The stitching method may be configured to produce an at least partially coherent image of the mask from time sequences of images from the EUV camera.

A plurality of image lines can be captured. The image lines collectively can cover the entire area of a region of a photomask to be examined. There may be an overlap between each pair of adjacent image lines. Adjacent image lines can extend parallel to one another in the longitudinal direction. There may be an overlap in the transverse direction. The overlap can extend over the entire length of the image lines involved. The inspection of a single photomask can involve, for example, between 50 and 1000 image lines, preferably between 100 and 500 image lines, being captured. For example, the inspection of the photomask can extend over a period of between 3 hours and 10 hours. For example, capturing a single image line can take between 1 minute and 5 minutes.

The plurality of image lines can be captured at successive times. For example, the directions of a movement of the photomask relative to the EUV camera for capturing every second image line may be identical except for influences by the corrective movement, the directions of the movements of the photomask relative to the EUV camera for capturing successive image lines preferably being able to be opposite except for influences by the corrective movement.

The plane of the photomask is called the X-Y plane. To capture an image line, the photomask is moved in the X direction by the positioning system. To switch between two image lines, the positioning system executes a movement in the Y direction. The corrective movement can comprise a movement within the X-Y plane. The corrective movement can comprise a shift within the X-Y plane and/or a rotation about an axis perpendicular to the X-Y plane.

The positioning system can have one or more additional degrees of freedom in addition or as an alternative to degrees of freedom within the X-Y plane. The degrees of freedom can include a linear movement in the Z direction. The degrees of freedom of the positioning system can include a tilting movement. The tilting axis can be an axis parallel to the photomask. The positioning system have two mutually orthogonal tilting axes. The positioning system can have a total of six degrees of freedom. The corrective movement can be a superimposition of movements that are within the X-Y plane and movements that lead out of the X-Y plane.

The projection lens can form a mechanical unit. The mechanical unit can comprise a frame bearing the optical elements of the projection lens. The optical elements can be mirror elements that have high reflectivity for EUV radiation. To enable the desired imaging of the photomask onto the image sensor of the EUV camera, the photomask must be arranged in a suitable position relative to the projection lens. The positioning system can be a mechanical unit, separate from the projection lens, that can be used to move the photomask relative to the projection lens.

The mask inspection device can comprise a measuring device to detect the position of the photomask relative to the projection lens. It can be an optical measuring device, for example in the form of an interferometer. The measuring device may be designed to detect the distance from one or more reference points. In one embodiment, the measuring device is mounted on the projection lens, and the reference points are in a known spatial relationship with the photomask. The reference points may, for example, be formed on the photomask itself or on a component of the positioning system. Alternatively, it is also possible for the measuring device to be in a known spatial relationship with the photomask, for example by virtue of the measuring device being mounted on the positioning system, and for the reference points to be formed on the projection lens.

The measured values supplied by the measuring device can be evaluated in order to obtain information about the actual position of the photomask relative to the projection lens. The actual position can be compared with a target position. A variance between the actual position and the target position can result in the positioning system being actuated by a first control signal in order to reduce the difference between the actual position and the target position. The movement of the positioning system can comprise a translation and/or a rotation. The movement can make use of all degrees of freedom of the positioning system.

Such a correction on the basis of measured values from the measuring device cannot correct imaging errors that result from a drift within the projection lens, as may arise, for example, from thermal deformations. Even if the photomask is in a suitable position relative to the projection lens with regard to the measured values, there may therefore be imaging errors. The invention therefore proposes processing an additional input variable when actuating the positioning system.

The additional input variable is determined by comparing an image structure obtained in an image line with a reference structure. It can be an image structure that extends on the photomask in the X direction, that is to say in the direction in which the photomask is moved when capturing an image line. If the imaging is error-free, such an image structure should extend in a direction of the captured image line that corresponds to the X direction. If the longitudinal direction of the image line corresponds to the X direction, the image structure in question extends parallel to the longitudinal direction of the image line if the imaging is error-free. The reference structure may be aligned and positioned as expected for the image structure when the imaging is error-free. If there is a variance between the image structure and the reference structure, the positioning system can be actuated in such a way that the variance is reduced.

The invention is not limited to a specific type of representation of the reference structure. The reference structure may be derived from a reference image and be in the form of image data. The reference structure may be defined by suitable coordinates. In one embodiment, the reference structure is obtained by use of pattern recognition. If, for example, it is known that a certain pattern is at a certain location on the photomask, this pattern can be sought in the image line and a variance between the alignment of the pattern in the image line and the alignment of the reference pattern can be determined.

In the method according to the invention, it is important for structures aligned in the X direction on the photomask to extend parallel to one another in the imaging onto the image sensor so that a complete image of the photomask can be produced from multiple contiguous image lines. The image lines can be captured in such a way that there is an overlap between two adjacent image lines in the Y direction. The image lines can be merged so that the image structures of the adjacent image lines match within the region of overlap. In particular, this can be accomplished by shifting the image lines relative to one another in the X direction. A drift having an effect in the X direction therefore does not necessarily mean that the image lines can no longer be merged to produce a flawless image. Irrespective of this, the method can be carried out in such a way that variances in the X direction are also determined and corrected by use of suitable actuation of the positioning system. The corrective movement can comprise a translation and/or a rotation of the photomask. The corrective movement can make use of all degrees of freedom of the positioning system.

Imaging errors having an effect in the Y direction can cause the width of the region of overlap to change. If the imaging error is so large that there is no longer any overlap between adjacent image lines, a complete image of the photomask can no longer be produced. The method according to the invention can be carried out in such a way that a region of overlap is maintained over the entire length between two adjacent image lines. As very large volumes of data, for example in the order of several 10 GB/second, are generated during the operation of the mask inspection device, it is desirable to keep the region of overlap as small as possible. The width of the region of overlap may be less than 10%, preferably less than 5%, more preferably less than 2% of the width of an image line.

A corrective movement of the positioning system triggered by a variance between an image structure and a reference structure can take place at discrete times. For example, a drift that occurred during the capture of the image line can be determined during or after the capture of a previous image line. A transition phase between the capture of the image line and the capture of an immediately following subsequent image line can be used to perform a corrective movement to correct the drift that has occurred. The corrective movement may be complete before the capture of the subsequent image line. A corresponding sequence of determination of a required corrective movement and execution of the corrective movement can be performed for multiple pairs of successive image lines, in particular for all pairs of successive image lines. Such a procedure has the advantage that an image line can be captured without a corrective movement being superimposed on the image.

It is also possible for a corrective movement of the photomask to be performed while an image line is captured. For this, it is advantageous if information about the variation in a drift over time is obtained from a comparison of an image structure with a reference structure. If a variation in the drift over time is known, the information can be used to control a continuous corrective movement of the positioning system. The corrective movement can continuously extend over the entire duration of the capture of an image line. In this way too, a correction that occurred during the capture of a previous image line can be corrected for the capture of a later image line.

An image sensor is exposed when EUV radiation strikes the image sensor and the image sensor uses the incident EUV radiation to produce charge carriers that can be read to obtain image data. For the purposes of the invention, an image is generated from image data when the image data are provided in a form that allows conclusions to be drawn about structures present on the photomask. Generating an image does not require the image to be physically produced or represented in a form that is perceptible to human beings.

The image sensor can comprise a multiplicity of pixels, and so a pixel array is defined by a multiplicity of pixel lines. The pixel lines can extend in a direction that corresponds to the X direction, which means that a movement of the photomask in the X direction corresponds to a movement parallel to the longitudinal direction of the pixel lines. It is also possible for the pixel lines to form a non-0° angle with the X direction. The angle may be smaller than 5°, preferably smaller than 2°, more preferably smaller than 1°. The pixel sensor may be designed to be read line by line. The width of an image line can be defined by the image data obtained with multiple pixel lines, in particular with all pixel lines, together.

The method can be carried out in such a way that charge carriers produced by incident EUV radiation in the image sensor are shifted from pixel to pixel within a pixel line before the number of charge carriers is read. The speed at which the charge carriers are shifted can be matched to the speed at which the photomask is moved in the X direction. This opens up the possibility of summing the charge carriers produced by the imaging, which has an advantageous effect on the accuracy and signal-to-noise ratio of the data obtained. The image sensor may be in the form of a CCD (Charge Coupled Device) sensor or in the form of a CMOS (Complementary Metal Oxide Semiconductor) sensor. In one embodiment, the image sensor is in the form of a TDI (Time Delay and Integration) sensor.

The photomask can have an aspect ratio of between 1:1 and 1:3, preferably between 1:1 and 1:2, particularly preferably of 1:1 or 1:2. The photomask can be substantially rectangular. The photomask can preferably have a length and a width of 5 to 7 inches (12.7 cm to 17.8 cm), particularly preferably a length and a width of 6 inches (15.2 cm). As an alternative thereto, the photomask can have a length of 5 to 7 inches (12.7 cm to 17.8 cm) and a width of 10 to 14 inches (25.4 cm to 35.6 cm), preferably a length of 6 inches (15.2 cm) and a width of 12 inches (30.5 cm).

The invention also relates to a control system for a mask inspection device, wherein the control system is designed to actuate an image sensor and a positioning system in such a way that, during an exposure process of the image sensor, a photomask borne by the positioning system is moved relative to a projection lens so that an image line is captured. The control system is further designed to take a comparison between an image structure included in the image line and a reference structure as a basis for generating a control signal for the positioning system so that the positioning system performs a corrective movement of the photomask. The invention further relates to a mask inspection device equipped with such a control system.

The invention also relates to a computer program product or set of computer program products, comprising program parts that, when loaded into a computer or into mutually networked computers connected to a control system according to the invention, are designed to carry out the method according to the invention.

The disclosure encompasses developments of the method comprising features that are described in the context of the control system according to the invention. The disclosure encompasses developments of the control system comprising features that are described in the context of the method according to the invention.

### BRIEF DESCRIPTION OF DRAWINGS

The invention is described by way of example below on the basis of advantageous embodiments with reference to the accompanying drawings, in which:

FIG. 1: shows a schematic representation of an example of a mask inspection device;

FIG. 2: shows a schematic representation of an example of a photomask;

FIG. 3: shows a schematic representation of aspects of an example of an EUV camera;

FIG. 4: shows a schematic representation of an example of a projection lens of the mask inspection apparatus;

FIG. 5: shows a schematic representation of an example of the image lines on a photomask without drift correction according to the invention;

FIG. 6: shows a schematic representation of a comparison between an image structure and a reference structure;

FIG. 7: shows a schematic representation of an example of the projection lens of the mask inspection device according to the invention with a control system;

FIG. 8: shows a schematic representation of an example of the image lines on a photomask with drift correction according to the invention.

### DETAILED DESCRIPTION

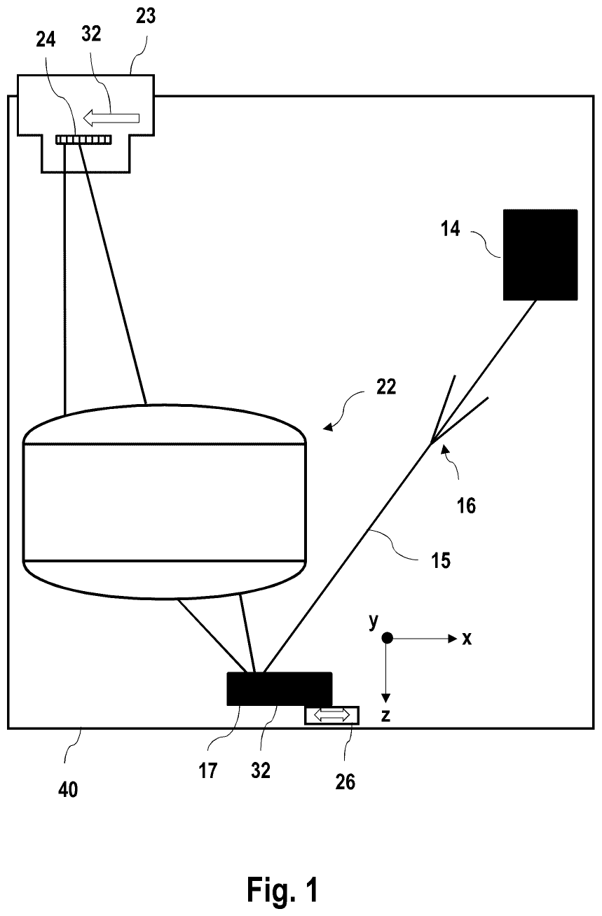

A mask inspection device shown in FIG. 1 can be used to examine microlithographic photomasks 17.

In general, microlithographic photomasks 17 are intended to be used in a microlithographic projection exposure apparatus (not shown). In the microlithographic projection exposure apparatus, the photomask 17 is illuminated with extreme ultraviolet radiation (EUV radiation) at a wavelength of for example 13.5 nm in order to image a structure formed on the photomask 17 onto the surface of a lithographic object in the form of a wafer. The wafer is coated with a photoresist that reacts to the EUV radiation. The mask inspection device is used to examine whether the photomask meets the requirements and is free from contamination.

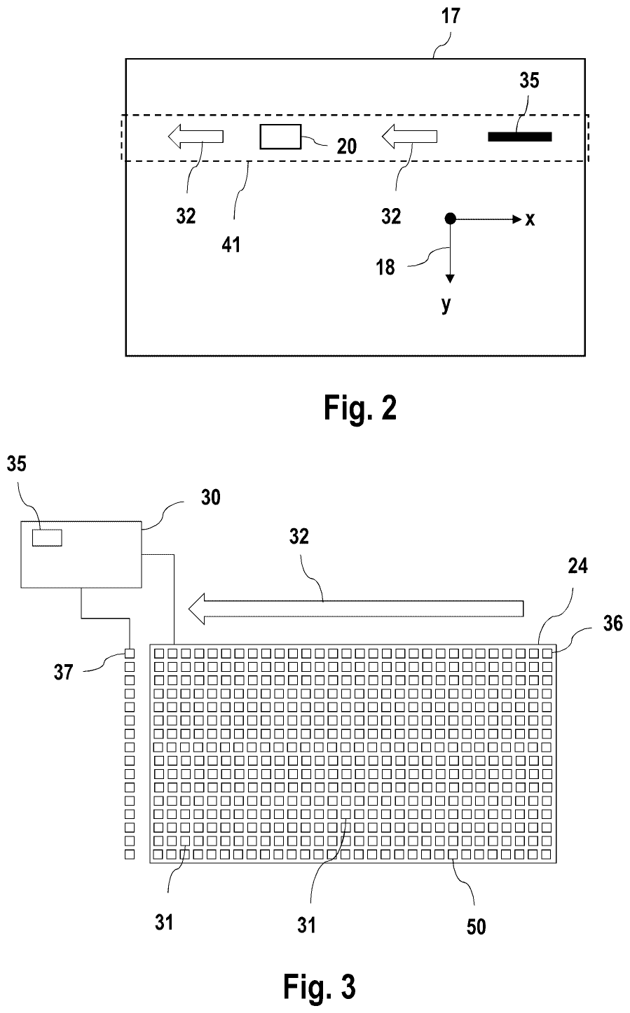

In accordance with FIG. 1, the photomask 17 is arranged in the mask inspection device in such a way that an EUV beam path 15 coming from an EUV radiation source 14 is directed onto the photomask 17 via an illumination system 16. The illumination system 16 is used to shape the EUV radiation to form a beam used to illuminate, with uniform brightness, an examination field 20 on the surface of the photomask 17. The examination field 20, which is small in comparison with the area of the photomask 17, is depicted in FIG. 2 in a representation that is not true to scale. For example, the illuminated region 20 may have dimensions of 0.5 mm×0.8 mm. A field stop used to limit the illuminated region to the examination field 20 on the surface of the photomask 17 is arranged in the illumination system 16. An XY positioning mechanism 26 can be used to move the photomask in the X-Y plane 18 in order to bring different examination fields 20 into the region of the EUV beam path 15. In some implementations, the XY positioning mechanism can be a generic positioning device that processes control signals to move the mask relative to the EUV beam path. For example, the XY positioning mechanism can include a first linear displacement drive configured to move the photomask along the X direction, a second linear displacement drive configured to move the photomask along the Y direction, and a control circuit configured to processes control signals and control the first and second linear displacement drives to move the photomask relative to the EUV beam path. Other positioning systems can also be used, for example, a positioning system that includes a rotary stage or table and a linear displacement drive to change the rotational and linear positions of the photomask.

The edge lengths of the photomask 17 can be between 100 mm and 200 mm, for example. The photomask can have an aspect ratio of between 1:1 and 1:3, preferably between 1:1 and 1:2, particularly preferably of 1:1 or 1:2. The photomask can be substantially rectangular. The photomask can preferably have a length and a width of 5 to 7 inches (12.7 cm to 17.8 cm), particularly preferably a length and a width of 6 inches (15.2 cm). As an alternative thereto, the photomask can have a length of 5 to 7 inches (12.7 cm to 17.8 cm) and a width of 10 to 14 inches (25.4 cm to 35.6 cm), preferably a length of 6 inches (15.2 cm) and a width of 12 inches (30.5 cm).

The EUV beam path 15 reflected from the photomask 17 continues through a projection lens 22 to an EUV camera 23 that is equipped with an image sensor 24. The projection lens is used to image the examination field 20 of the photomask 17 onto the image sensor 24 of the EUV camera 23. The EUV radiation source 14, the illumination system 16, the photomask 17, the projection lens 22 and the EUV camera 23 are arranged in a vacuum housing 40 in which negative pressure prevails during the operation of the mask inspection device.

The EUV radiation source 14 is a plasma radiation source in which the EUV radiation is emitted from a plasma at a wavelength of 13.5 nm. Tin is a medium that can be used to generate a plasma suitable for emitting such EUV radiation. A laser beam can be made to impinge on a droplet of the medium for the purpose of generating the plasma.

The illumination system 16 and the projection lens 22 can comprise mirrors from which the EUV radiation is reflected. The mirrors may be designed as EUV mirrors, which have particularly high reflectivity for EUV radiation. The optical area of the EUV mirrors can be formed by a highly reflective coating. This may be a multilayer coating, in particular a multilayer coating having alternating layers of molybdenum and silicon. Using such a coating, it is possible to reflect approximately 70% of the incident EUV radiation.

The projection lens 22 has a magnification factor of more than 100. In order to be able to capture the entirety of the image produced by the examination field 20 of the photomask 17, the area of the image sensor 24 is greater than the area of the examination field 20 in accordance with the magnification factor. For example, the image sensor 24 can have dimensions of the order of magnitude of 100 mm to 200 mm. The image sensor 24 comprises a multiplicity of parallel pixel lines 36 that define a pixel array 50. The image sensor 24 is aligned in such a way that the longitudinal direction of the pixel lines 36 corresponds to the X direction. When the photomask 17 is moved in the X direction, the image of the photomask 17 on the image sensor 24 moves parallel to the longitudinal direction of the pixel lines 36.

According to FIG. 3, the EUV camera 23 comprises a control unit 30, which is in communication with the image sensor 24. The control unit 30 actuates the image sensor 24, among other things to determine the times at which the image sensor 24 is exposed in order to take an image capture. In each pixel 31, the amount of incident EUV radiation is then recorded and converted into a corresponding number of free charge carriers. Image data can be obtained by reading the number of charge carriers for the individual pixels 31.

The image sensor 24 is read by shifting the charge carriers produced by a pixel 31 in each pixel line 36 from pixel to pixel in the scan direction 32. With each shift step, the charge carriers from the last pixel of a pixel line 36 are shifted to a readout cell 37. The number of charge carriers is determined in the readout cell 37. Information about the number of charge carriers in a readout cell 37 is transmitted to the control unit 30 as image information.

The image sensor 24 may be configured such that in a reading step the charge carriers are shifted by a pixel 31 in all pixel lines 36 simultaneously, so that charge carriers for each pixel line 36 are transmitted to an associated readout cell 37. The image data obtained with all pixel lines 36 together define the width of an image line 40. An image line 40 extends in the X direction over the entire length of the photomask 17. Multiple parallel image lines 40 are used to produce an image of the entire photomask 17.

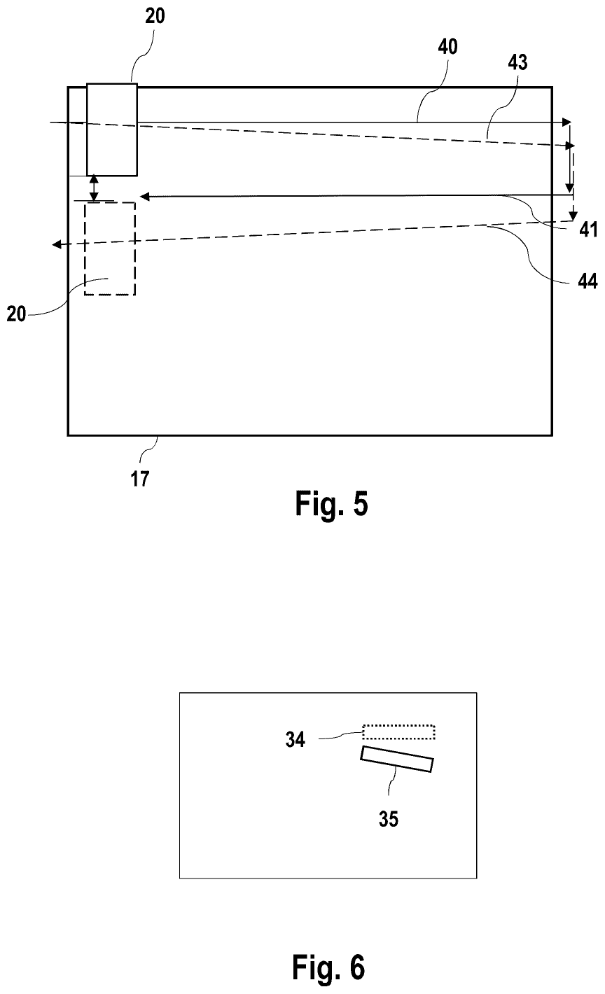

As a result of the photomask 17 being moved relative to the image sensor 24 by the positioning system 26 during an exposure process of the image sensor 24, the examination field 20, as shown schematically in FIG. 5, is guided over the photomask 17 in the X direction so that a first image line 40 is captured. This captures the first image line in a continuous exposure process. In an image line 40 captured by the image sensor 24, an image structure 35 that extends on the photomask 17 in the X direction has an alignment that is parallel to the longitudinal direction of the image lines 36.

Subsequently, there is a switch from the first image line 40 to a second image line 41 by virtue of the positioning system 26 executing a movement in the Y direction. The second image line 41 has an opposite scanning direction to the first image line 40, with the result that the examination field 20 is guided over the photomask 17 in the negative X direction so that an image line 41 is captured. This process is repeated until the entire photomask 17 has been exposed.

To allow a complete image of the photomask to be produced from the contiguous image lines, the image lines are captured in such a way that there is an overlap between the adjacent image lines in the Y direction. Image structures in a region of overlap can then be taken as a basis for combining the image lines to produce an overall image of the photomask.

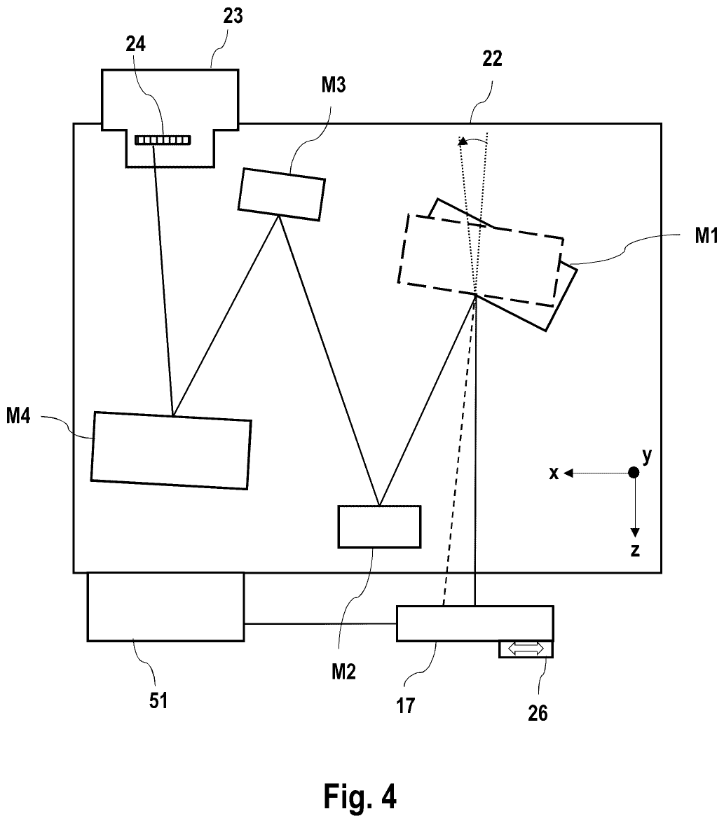

The quality of the image on the image sensor depends on the precise positioning of the photomask 17. The relative position of the photomask 17 in relation to the projection lens 22 is measured, as shown in FIG. 4, using a measuring device 51 mounted on the projection lens 22. The measuring device 51 is embodied as an interferometer and measures the distance from multiple reference points on the photomask 17. A measurement signal from the measuring device 51 is used to actuate the positioning system 26 and align the photomask 17 relative to the projection lens 22.

In some implementations, the projection lens 22 comprises multiple optical elements M1-M4 that are used to direct the EUV beam path from the photomask to the EUV camera 23 and the image sensor 24. Due to thermal influences, there may be drifts in the projection lens 22, which can lead to a change in the position of the optical elements M1-M4 of the projection lens 22. This can result in a shift of the examination field 20 on the photomask. These drifts within the projection lens 22 are not detected by the measuring device 51 and thus not corrected either.

As a result, the examination field 20, as shown schematically in FIG. 5, is guided over the photomask, due to drift, in such a way that a first image line 43 and a second image line 44 are captured. The resulting image lines 43 and 44 are spaced in the Y direction such that there is no region of overlap between the image lines 43 and 44. To ensure the region of overlap between adjacent image lines that is required for image quality, the drift-related variances must be corrected according to the invention.

Such a drift error can be detected by comparing an image structure 35 captured by use of the image lines 43, 44 with a reference structure 34, see FIG. 6. In some implementations, the reference structure may be obtained from a design file representing patterns of the mask. Information about the reference structure may be retrieved from a data storage device that stores a design file for the patterns of the mask. The reference structure may be represented in a reference image. The coordinate system of the reference image may be referenced to the coordinate system of a captured image including the image structure, in such a way that it is possible to relate a direction in the reference image to a direction in the captured image. On the basis of the comparison, it is recognized that the image structure 35 does not have the expected alignment within the image line 43, 44.

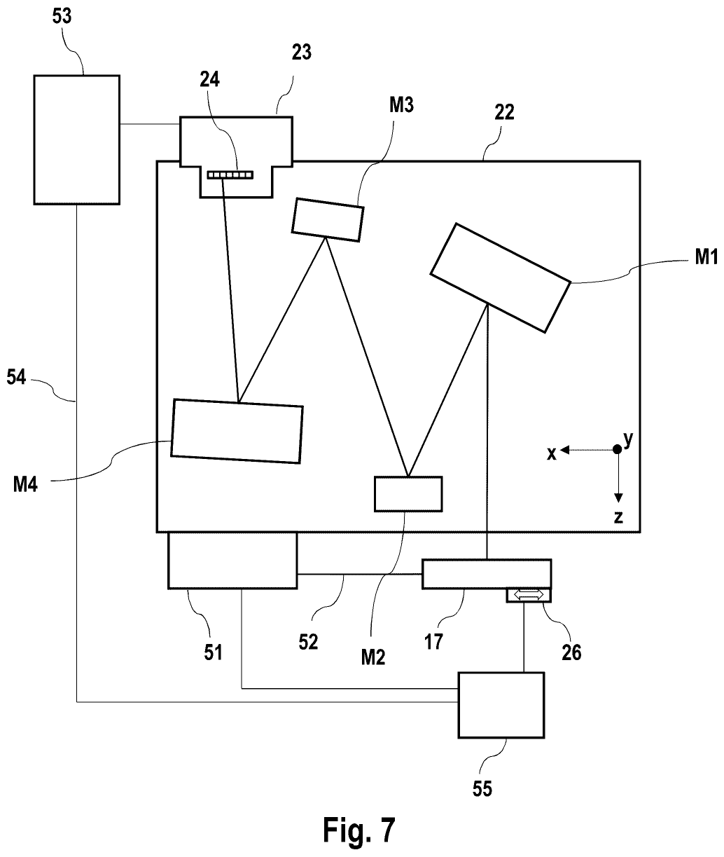

As shown in FIG. 7, the image structures of the individual image lines 43, 44 that are captured by the EUV camera 23 using the image sensor 24 are evaluated by a computer 53 in order to perform a comparison between the image structure 35 and the reference structure 34. A signal 54 is generated from the variance between the captured image structure 35 and the reference structure 34 and is transferred to a control unit 55. In some implementations, the computer 53 can implement a process or algorithm that includes analyzing the reference image to identify the reference structure, analyzing the captured image to identify the image structure, identifying a deviation between coordinates of the reference structure in the reference image and coordinates of the image structure in the captured image, identifying a deviation between a first direction derived from the reference structure in the reference image and a corresponding second direction derived from the image structure in the captured image, and determining a corrective movement (e.g., represented by signal 54) to be performed by the positioning system that corrects the deviation between the first direction and the second direction. The process can include using generic image processing methods to identify structures within an image.

In some implementations, the control unit 55 can be a generic control unit having electronic circuitry designed to process input signals in order to generate control signals for the positioning system. The input signals may represent the deviation between the reference structure and the image structure. The input signals may represent the deviation between the first direction and the second direction. For example, the control unit 55 can include a digital signal processor, or a data processor such as a central processing unit (CPU). The data processor can include one or more processor cores, and each processor core can include logic circuitry for processing data. For example, a data processor can include an arithmetic and logic unit (ALU), a control unit, and various registers. Each data processor can include cache memory. Each data processor can include a system-on-chip (SoC) that includes multiple processor cores, random access memory, graphics processing units, one or more controllers, and one or more communication modules. Each data processor can include many transistors.

The control unit 55 is used to actuate the positioning system 26 of the photomask 17 in such a way that the positioning system 26 performs a corrective movement so that the X direction of the movement of the photomask 17 again corresponds to the longitudinal direction of the pixel lines 36.

In addition, variances in the target position of the photomask relative to the projection lens 22 that are detected by the measuring device 51 are transferred to the control unit 55. The control unit 55 actuates the positioning system 26 in such a way that the corrective movement compensates both for the variances from the relative position of the photomask 17 in relation to the projection lens 22 and for drift-related variances.

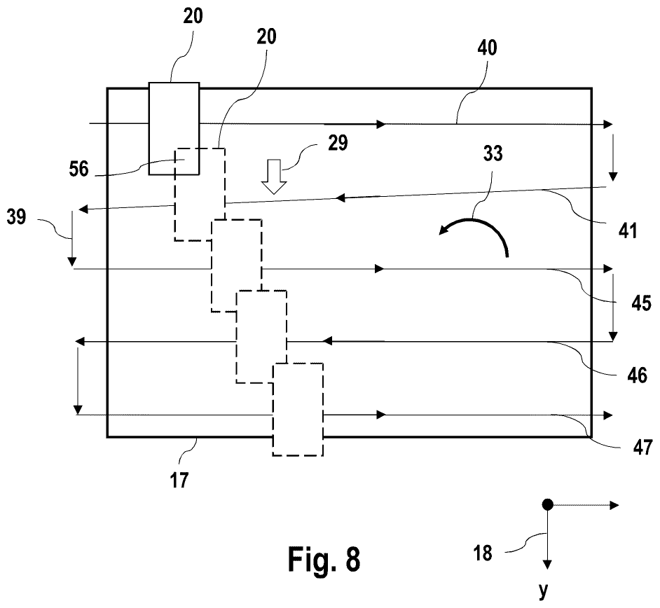

FIG. 8 shows a schematic representation of the image lines illuminated on the photomask 17 with a corrective movement 33 of the positioning system 26. The examination field 20 is guided along the image lines 40, 41, 45, 46, 47 by implementing the corrective movements of the positioning system 26. Within the second image line 41, a schematically indicated drift 29 occurs, which is detected by way of a comparison between an image structure 35 and a reference structure 34. In a transition phase 39 between the second image line 41 and a subsequent image line 45, the positioning system 26 is actuated in such a way that the photomask 17 executes a corrective movement 33 within the X-Y plane 18 in the form of a rotation about an axis perpendicular to the X-Y plane, with the result that the X direction is again aligned with the longitudinal direction of the pixel lines 36. The resulting image lines 40, 41, 45, 46, 47 are laterally spaced in such a way that the image lines overlap one another in the Y direction in a region of overlap 56. The width of the region of overlap 56 is less than 2% of the width of an image line. The regions of overlap between adjacent image lines are used to assemble the individual image lines into an overall image. In some examples, the corrective movements can include a tilting movement about a tilting axis parallel to the photomask.

In some implementations, the computer 53 can include one or more computing devices, each computing device including one or more data processors for processing data, one or more storage devices for storing data, and/or one or more computer programs including instructions that when executed by the one or more computing devices cause the one or more computing devices to carry out the processes. The one or more computing devices can include one or more input devices, such as a keyboard, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computing devices can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

A number of embodiments of the invention have been described. Nevertheless, it will be understood that various modifications can be made without departing from the spirit and scope of the invention. For example, the number of optical elements (e.g., M1, M2, etc.) in the projection lens 22 can be different from the examples described above.

While some embodiments, examples or aspects described herein include some but not other features included in other embodiments, examples or aspects combinations of features of different embodiments, examples or aspects are meant to be within the scope of the claims, and form different embodiments, as would be understood by those skilled in the art. The embodiments of the present invention that are described in this specification and the optional features and properties respectively mentioned in this regard should also be understood to be disclosed in all combinations with one another. The description of a feature comprised by an embodiment—unless explicitly explained to the contrary—should also not be understood such that the feature is essential or indispensable for the function of the embodiment. Accordingly, other embodiments are within the scope of the following claims.

What is claimed is:

1. A method for operating a mask inspection device, in which a photomask illuminated with EUV radiation is imaged onto an image sensor of an EUV camera by a projection lens, the photomask being borne by a positioning system, the positioning system being designed to change the position of the photomask relative to the projection lens, wherein the photomask is moved relative to the projection lens during an exposure process of the EUV camera so that an image line is captured, wherein an image structure included in the image line is compared with a reference structure, and wherein a variance between the image structure and the reference structure results in the positioning system being actuated in order to perform a corrective movement of the photomask.

2. The method of claim 1, wherein a plurality of image lines are captured and wherein there is an overlap between each pair of adjacent image lines.

3. The method of claim 1, wherein the corrective movement comprises a movement within the X-Y plane, the X-Y plane corresponding to a plane defined by the photomask.

4. The method of claim 3, wherein the corrective movement comprises a translation within the X-Y plane.

5. The method of claim 3, wherein the corrective movement comprises a rotation about an axis perpendicular to the X-Y plane.

6. The method of claim 1, wherein the corrective movement comprises a tilting movement about a tilting axis parallel to the photomask.

7. The method of claim 1, wherein a measuring device is used to detect the position of the photomask relative to the projection lens.

8. The method of claim 7, wherein the measuring device is embodied as an optical measuring device, in particular as an interferometric measuring device.

9. The method of claim 1, wherein the image structure included in the image line images a structure that extends on the photomask in the X direction, the X direction corresponding to the direction in which the photomask is moved during an exposure process of the EUV camera.

10. The method of claim 1, wherein a plurality of corrective movements of the photomask are performed and wherein the corrective movements take place at discrete times.

11. The method of claim 1, wherein the corrective movement of the photomask or part of the corrective movement of the photomask is performed in a transition phase between the capture of a first image line and the capture of an immediately subsequent second image line.

12. The method of claim 1, wherein the corrective movement of the photomask or part of the corrective movement of the photomask is performed while an image line is captured.

13. The method of claim 1, wherein a drift that occurred during the capture of a first image line is determined and wherein a corrective movement of the photomask to correct the drift is performed before the capture of a later second image line.

14. A control system for a mask inspection device, wherein the control system is designed to actuate an image sensor and a positioning system in such a way that, during an exposure process of the image sensor, a photomask borne by the positioning system is moved relative to a projection lens so that an image line is captured, and wherein the control system is designed to take a comparison between an image structure included in the image line and a reference structure as a basis for generating a control signal for the positioning system so that the positioning system performs a corrective movement of the photomask.

15. A mask inspection device, comprising an EUV camera, a positioning system for a photomask and a projection lens in order to image the photomask onto an image sensor of the EUV camera, the positioning system being designed to move the photomask while the image sensor is exposed so that an image line is captured, further comprising a control system of claim 14 for actuating the positioning system.

16. A computer program product or set of computer program products, comprising program parts that, when loaded into a computer or into mutually networked computers connected to a control system of claim 14, are designed to carry out a method for operating a mask inspection device, in which a photomask illuminated with EUV radiation is imaged onto an image sensor of an EUV camera by a projection lens, the photomask being borne by a positioning system, the positioning system being designed to change the position of the photomask relative to the projection lens, wherein the photomask is moved relative to the projection lens during an exposure process of the EUV camera so that an image line is captured, wherein an image structure included in the image line is compared with a reference structure, and wherein a variance between the image structure and the reference structure results in the positioning system being actuated in order to perform a corrective movement of the photomask.

17. The computer program product or set of computer program products of claim 16, wherein as part of carrying out the method for operating the mask inspection device, a plurality of image lines are captured and wherein there is an overlap between each pair of adjacent image lines.

18. The computer program product or set of computer program products of claim 16, wherein as part of carrying out the method for operating the mask inspection device, the corrective movement comprises a movement within the X-Y plane, the X-Y plane corresponding to a plane defined by the photomask.

19. The computer program product or set of computer program products of claim 16, wherein in carrying out the method for operating the mask inspection device, the corrective movement comprises a translation within the X-Y plane.

20. The computer program product or set of computer program products of claim 16, wherein in carrying out the method for operating the mask inspection device, the corrective movement comprises a rotation about an axis perpendicular to the X-Y plane.
